(19) United States
(12) Patent Application Publication
(10) Pub. No.: US 2025/0194193 A1
(43) Pub. Date: Jun. 12, 2025

(54) ARSENIC DIFFUSION PROFILE ENGINEERING FOR TRANSISTORS

(71) Applicant: Applied Materials, Inc., Santa Clara, CA (US)

(72) Inventors: Patricia M. LIU, Saratoga, CA (US); Flora Fong-Song CHANG, Saratoga, CA (US); Zhiyuan YE, San Jose, CA (US)

(21) Appl. No.: 19/055,798

(22) Filed: Feb. 18, 2025

Related U.S. Application Data
(63) Continuation of application No. 17/628,634, filed on Jan. 20, 2022, now Pat. No. 12,249,626.
(60) Provisional application No. 62/881,710, filed on Aug. 1, 2019.

(51) Int. Cl. H10D 62/834; H01L 21/02; H01L 21/22; H10D 30/01; H10D 30/62

(52) U.S. Cl. CPC H10D 62/834; H01L 21/02463; H01L 21/2205; H10D 30/0241; H10D 30/62

(57) ABSTRACT

Embodiments of the present disclosure relate to methods for forming a source/drain extension. In one embodiment, a method for forming an nMOS device includes forming a gate electrode and a gate spacer over a first portion of a semiconductor fin, removing a second portion of the semiconductor fin to expose a side wall and a bottom, forming a silicon arsenide (Si:As) layer on the side wall and the bottom, and forming a source/drain region on the Si:As layer. During the deposition of the Si:As layer and the formation of the source/drain region, the arsenic dopant diffuses from the Si:As layer into a third portion of the semiconductor fin located below the gate spacer, and the third portion becomes a doped source/drain extension region. By utilizing the Si:As layer, the doping of the source/drain extension region is controlled, leading to reduced contact resistance while reducing dopants diffusing into the channel region.

### CROSS-REFERENCE TO RELATED APPLICATIONS

This application is a continuation application of U.S. patent application Ser. No. 17/628,634, filed Jan. 20, 2022, which claims priority to United States Patent Application PCT/US2020/040535, filed Jul. 1, 2020, which claims priority to U.S. Patent Application Ser. No. 62/881,710, filed Aug. 1, 2019, all of which are incorporated herein by reference in its entirety.

### BACKGROUND

### Field

Embodiments of the present disclosure generally relate to methods for forming a transistor, and more particularly relate to methods for forming a source/drain extension.

### Description of the Related Art

The transistor is a key component of most integrated circuits. Since the drive current, and therefore speed, of a transistor is proportional to the gate width of the transistor, faster transistors generally require larger gate width. Thus, there is a trade-off between transistor size and speed, and “fin” field-effect transistors (FinFETs) have been developed to address the conflicting goals of a transistor having maximum drive current and minimum size. FinFETs are characterized by a fin-shaped channel region that greatly increases the size of the transistor without significantly increasing the footprint of the transistor, and are now being applied in many integrated circuits. However, FinFETs are still associated with some drawbacks.

For example, in n-channel metal-oxide semiconductor (nMOS) devices, strong diffusion of phosphorous atoms from heavily phosphorus doped silicon (Si:P) regions into the channel is a concern in smaller FinFETs. Thus, while higher concentrations of phosphorous atoms allows very low contact resistance and can beneficially reduce resistivity in the source and drain regions of a FinFET, the risk of phosphorus atoms diffusion from a source/drain extension into the channel is greatly increased, particularly for FinFETs having smaller dimensions.

Therefore, there is a need for an improved method to form a transistor.

### SUMMARY

Embodiments of the present disclosure generally relate to methods for forming a transistor, and more particularly relate to methods for forming a source/drain extension. In one embodiment, a transistor includes a gate electrode structure disposed over a channel region, a source/drain extension region doped with arsenic disposed adjacent to the channel region, an arsenic doped silicon layer disposed on the source/drain extension region, and a source/drain region disposed on the arsenic doped silicon layer.

In another embodiment, a method for forming a transistor includes removing a first portion of a semiconductor fin to expose a side wall and a bottom, and a second portion of the semiconductor fin is disposed below a gate electrode structure. The method further includes forming an arsenic doped silicon layer on the side wall and the bottom by a selective epitaxial deposition process, and forming a source/drain region on the arsenic doped silicon layer while doping the second portion of the semiconductor fin with arsenic.

In another embodiment, a non-transitory computer readable storage medium having stored thereon a plurality of instructions, the plurality of instructions including instructions to control components of a processing system to perform the process of removing a first portion of a semiconductor fin to expose a side wall and a bottom, and a second portion of the semiconductor fin is disposed below a gate electrode structure. The process further includes forming an arsenic doped silicon layer on the side wall and the bottom by a selective epitaxial deposition process, and forming a source/drain region on the arsenic doped silicon layer while doping the second portion of the semiconductor fin with arsenic.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a schematic perspective view of a FinFET, according to an embodiment of the disclosure.

FIG. 2 is a schematic cross-sectional view of the FinFET of FIG. 1, according to an embodiment of the disclosure.

FIG. 3 is a flowchart of a process for forming a FinFET of FIG. 1, according to an embodiment of the disclosure.

FIGS. 4A-4D are schematic cross-sectional views of a semiconductor device corresponding to various stages of the process of FIG. 3, according to an embodiment of the disclosure.

FIG. 5 is a schematic top-view diagram of an example multi-chamber processing system suitable for performing the process of FIG. 3.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure relate to methods for forming a source/drain extension. In one embodiment, a method for forming an nMOS device includes forming a gate electrode and a gate spacer over a first portion of a semiconductor fin, removing a second portion of the semiconductor fin to expose a side wall and a bottom, forming an arsenic doped silicon (Si:As) layer on the side wall and the bottom, and forming a source/drain region on the Si:As layer. During the deposition of the Si:As layer and the formation of the source/drain region, the arsenic dopant diffuses from the Si:As layer into a third portion of the semiconductor fin located below the gate spacer, and the third portion becomes a doped source/drain extension region. By utilizing the Si:As layer, the doping of the source/drain extension region is controlled, leading to reduced contact resistance while reducing dopants diffusing into the channel region.

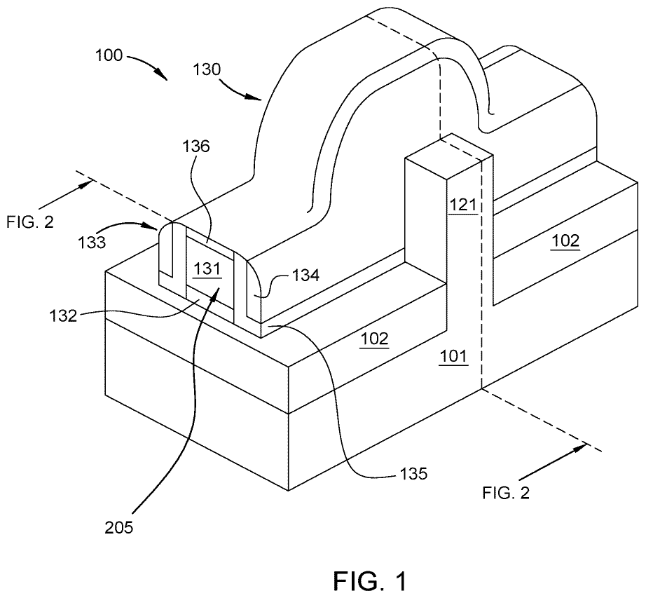

FIG. 1 is a schematic perspective view of a FinFET 100, according to an embodiment of the disclosure. The FinFET 100 includes a semiconductor substrate 101, insulation regions 102 disposed on the semiconductor substrate 101, a semiconductor fin 121 extending from the semiconductor substrate 101, and a gate electrode structure 130 disposed on the insulation regions 102 and the semiconductor fin 121. A top portion of the semiconductor fin 121 is exposed and electrically coupled to a source contact (not shown) of the FinFET 100, another top portion of semiconductor fin 121 is exposed and electrically coupled to a drain contact (not shown) of the FinFET 100, and a center portion of the semiconductor fin 121 includes the channel region of the FinFET 100. The gate electrode structure 130 serves as the gate of the FinFET 100.

The semiconductor substrate 101 may be a bulk silicon (Si) substrate, a bulk germanium (Ge) substrate, a bulk silicon-germanium (SiGe) substrate, or the like. The insulation regions 102, alternatively referred to as shallow trench isolation (STI), may include one or more dielectric materials, such as silicon dioxide (SiO₂), silicon nitride (Si₃N₄), or multiple layers thereof. The insulation regions 102 may be formed by high-density plasma (HDP), flowable chemical vapor deposition (FCVD), or the like.

A fin spacer (not shown for clarity) may be disposed on sidewalls of the semiconductor fin 121. The semiconductor fin 121 may be formed from the semiconductor substrate 101 or from a different semiconductor material that is deposited on the semiconductor substrate 101. In the latter case, the different semiconductor material may include silicon-germanium, a III-V compound semiconductor material, or the like.

The gate electrode structure 130 includes a gate electrode layer 131, a gate dielectric layer 132, the gate spacers 133, and a mask layer 136. In some embodiments, the gate electrode layer 131 includes a polysilicon layer or a metal layer that is capped with a polysilicon layer. In other embodiments, the gate electrode layer 131 includes a material selected from metal nitrides (such as titanium nitride (TiN), tantalum nitride (TaN) and molybdenum nitride (MoNx)), metal carbides (such as tantalum carbide (TaC) and hafnium carbide (HfC)), metal-nitride-carbides (such as TaCN), metal oxides (such as molybdenum oxide (MoOx)), metal oxynitrides (such as molybdenum oxynitride (MoOxNy)), metal silicides (such as nickel silicide), and combinations thereof. The gate electrode layer 131 can also be a metal layer capped with a polysilicon layer.

The gate dielectric layer 132 may include silicon oxide (SiOx), which may be formed by a thermal oxidation of the semiconductor fin 121. In other embodiments, the gate dielectric layer 132 is formed by a deposition process. Suitable materials for forming the gate dielectric layer 132 include silicon oxide, silicon nitrides, oxynitrides, metal oxides such as HfO2, HfZrOx, HfSiOx, HfTiOx, HAlOx, and combinations and multi-layers thereof. The gate spacers 133 are formed on sidewalls of the gate electrode layer 131, and each gate spacer 133 includes a nitride portion 134 and/or an oxide portion 135 as shown. In some embodiments, the mask layer 136 is formed on gate electrode layer 131 as shown, and may include silicon nitride.

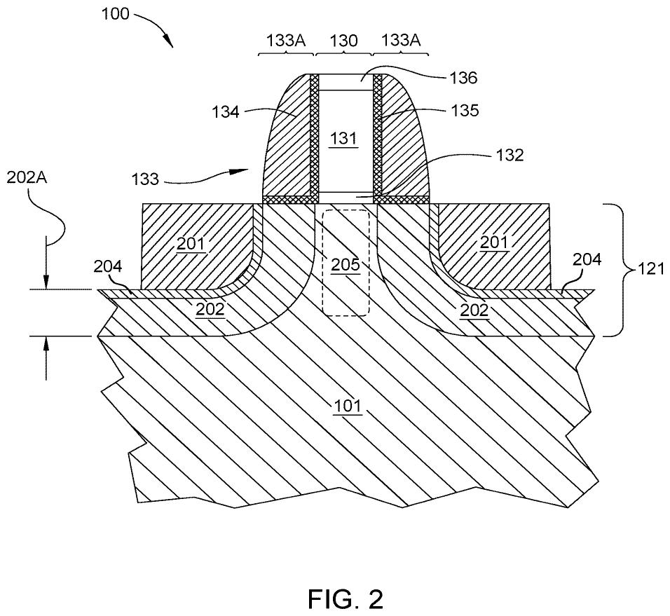

FIG. 2 is a schematic cross-sectional view of FinFET 100, according to an embodiment of the disclosure. The cross-sectional view illustrated in FIG. 2 is taken at section A-A in FIG. 1. As shown in FIG. 2, the FinFET 100 includes the semiconductor fin 121 with source and drain regions 201, Si:As layers 204, source and drain extension regions 202, and a channel region 205.

The source and drain regions 201 include relatively high concentrations of dopants, such as n-type dopants, for example phosphorus (P) or arsenic (As). For example, in some embodiments, a concentration of n-type dopants in the source and drain regions 201 may be as high as 5E21 atoms/cm³. The source and drain regions 201 may be produced by any suitable method. In one embodiment, the source and drain regions 201 are formed by an in-situ doping of a semiconductor layer using an epitaxial deposition process. In another embodiment, the source and drain regions are formed by first depositing a semiconductor layer and then doping the deposited semiconductor layer.

Each source/drain region 201 is disposed on the Si:As layer 204. The Si:As layer 204 has a thickness ranging from about 1 nm to about 10 nm. The Si:As layer 204 may be deposited by any suitable method, such as an epitaxial deposition process. The source and drain extension regions 202 is doped with As. In some embodiments, source and drain extension regions 202 are formed with a thickness 202A that is substantially the same as the width 133A of gate spacers 133.

With the small geometries associated with modern FinFET devices, a width 133A of gate spacers 133, which is also approximately the distance between the channel region 205 and the source/drain region 201, can be just a few nanometers. Conventionally, the undoped source and drain extension regions are first removed, and doped source and drain extension regions are formed on both sides of the channel region. Dopant can diffuse into the channel region during the formation of the doped source and drain extension regions. Alternatively, doping the undoped source and drain extension regions by any doping method can also lead to diffusion of dopant into the channel region.

In order to form the doped source and drain extension regions 202 without the risk of dopant diffusion into the channel region 205, the Si:As layers 204 are utilized. During the deposition of the Si:As layers 204 and the deposition of the source and drain regions 201, As atoms diffuse into the source and drain extension regions 202 from the Si:As layers 204. The diffusion of the As atoms from the Si:As layers 204 can be controlled by controlling the amount of excessive point defects in the Si:As layers 204. By depositing the Si:As layers 204 at a lower temperature, such as from about 500degrees Celsius to about 700 degrees Celsius, and a high deposition rate, such as about 50 Angstroms per minute to about 500 Angstroms per minute, the Si:As layers 204 as deposited are point defect rich. During the deposition of the source and drain regions 201, the deposition temperature, such as from about 500 degrees Celsius to about 700 degrees Celsius, increases As atoms diffusion into the source and drain extension regions 202 due to the point defect flux in the Si:As layers 204. Near the end of the deposition of the source and drain regions 201, the excessive point defects in the Si:As layers 204 move to the interface between the Si:As layer 204 and the source/drain extension region 202, which stops the diffusion of the As atoms from the Si:As layers 204 to the source/drain extension region 202. Therefore, the amount of excessive point defects in the Si:As layers 204 controls the As atoms diffusion depth. In other words, during the deposition of the source and drain regions 201, the excessive point defects are depleted in the Si:As layers 204, the source and drain regions 201 and the exposed surfaces to the chamber environment, which stops the As atoms from further diffusing from the Si:As layers 204 to the source and drain extension layers 202. In some embodiments, the diffusion of As atoms from the Si:As layers 204 to the source and drain extension layers 202 can be control by performing a thermal treatment process on the Si:As layers 204 prior to depositing the source and drain regions 201. The thermal treatment process may be a spike anneal process.

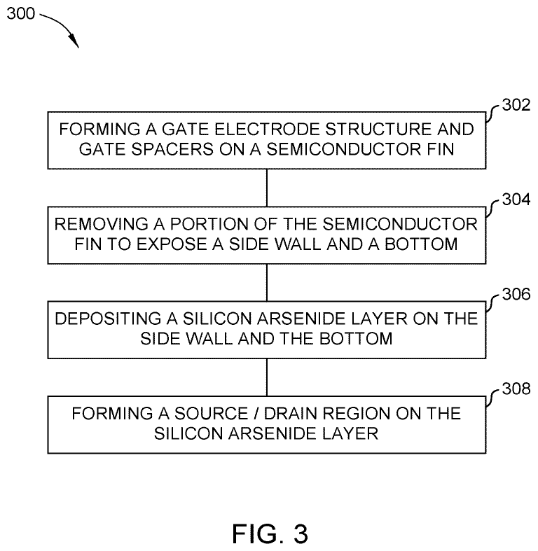

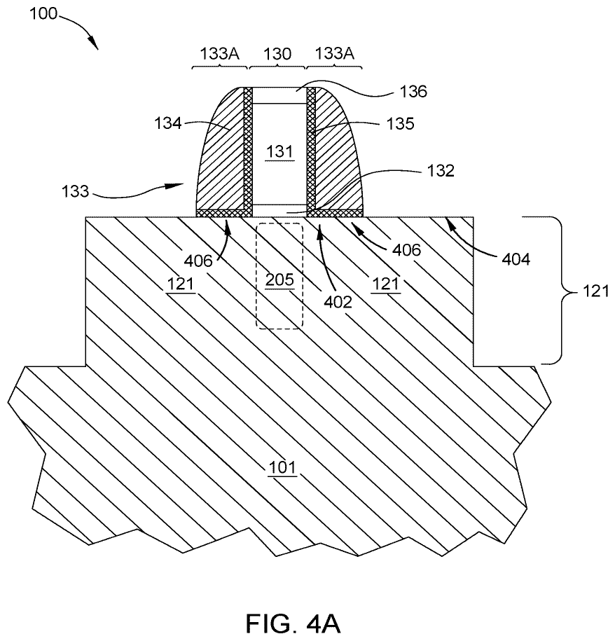

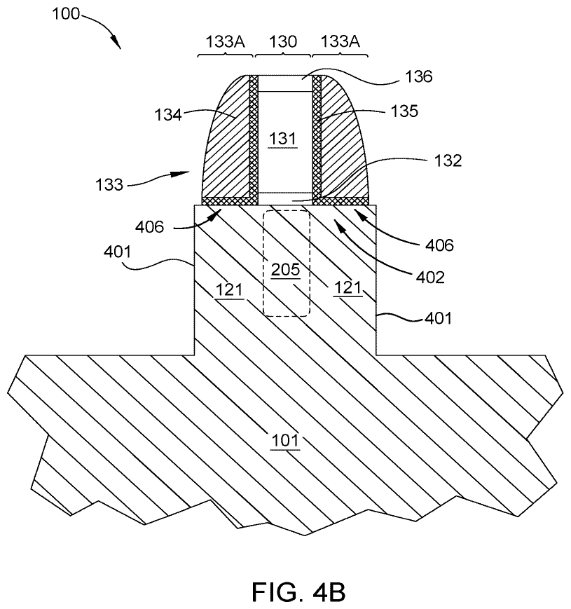

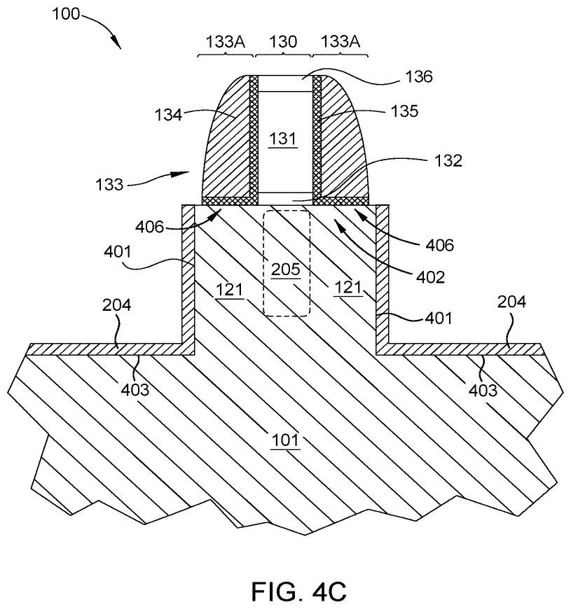

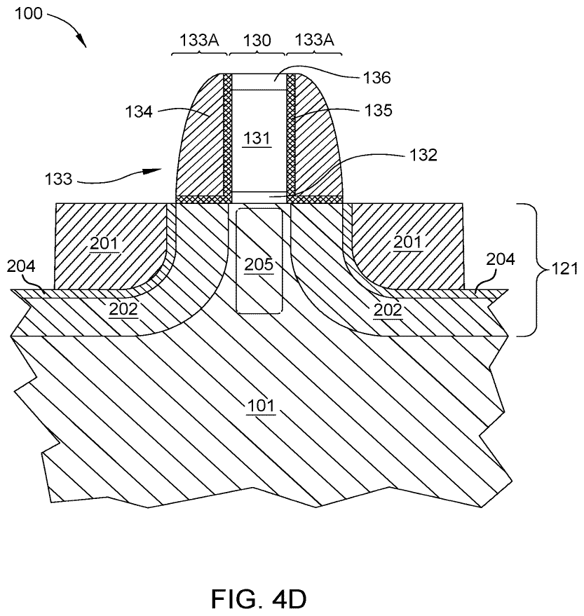

FIG. 3 is a flowchart of a process 300 for forming an nMOS FinFET, according to an embodiment of the disclosure. FIGS. 4A-4D are schematic cross-sectional views of a semiconductor device corresponding to various stages of the process 300 according to an embodiment of the disclosure. Although the process 300 is illustrated for forming an n-type doped source/drain extension region, the process 300 may be employed to form other structures on a substrate as well. The process 300 starts at operation 302, in which the gate electrode structure 130 and the gate spacers 133 are formed on the semiconductor fin 121, as shown in FIG. 4A. The gate electrode structure 130 and the gate spacers 133 are disposed on a first portion 402 of the semiconductor fin 121, and a second portion 404 of the semiconductor fin is exposed. The first portion 402 of the semiconductor fin 121 includes the channel region 205 disposed below the gate electrode structure 130 and a third portion 406 disposed below the gate spacers 133.

At operation 304, an etch process is performed to remove the second portion 404 of the semiconductor fin 121, as shown in FIG. 4B. The etch process may be an anisotropic etch process. The anisotropic etch process may be, for example, a deep reactive-ion etch (DRIE) process during which gate electrode structure 130 and gate spacers 133 are masked. The etch process exposes side walls 401 of the third portion 406 of the semiconductor fin and bottoms 403. The bottoms 403 may be a surface of the semiconductor substrate 101.

At operation 306, the Si:As layer 204 is deposited on the side wall 401 and the bottom 403, as shown in FIG. 4C. The Si:As layer 204 may have a thickness ranging from about 1 nm to about 10 nm. The Si:As layer 204 may be deposited by an epitaxial deposition process, such as a selective epitaxial deposition process. For example, the Si:As layer 204 is deposited on the side wall 401 and the bottom 403, which are fabricated from a semiconductor material, such as Si, and the Si:As layer 204 is not deposited on the gate spacers 133 and the mask layer 136, which are fabricated from a dielectric material. The deposition process may be performed at a chamber pressure ranging from about 1 Torr to about 600 Torr, such as from about 10 Torr to about 20 Torr, and at a deposition temperature (temperature of the substrate) ranging from about 500 degrees Celsius to about 700 degrees Celsius, such as from about 600 degrees Celsius to about 625 degrees Celsius. A silicon containing precursor and an arsenic containing precursor are flowed into the process chamber. The silicon containing precursor may be silane, disilane, dichlorosilane (DCS), trichlorosilane (TCS), or any suitable silicon containing precursor. The silicon containing precursor may include two or more silicon containing gases. The silicon containing precursor may have a flow rate ranging from about 1 sccm to about 1000 sccm, such as 1 sccm to about 500 sccm, or 10 sccm to about 1000 sccm. The arsenic containing precursor may be arsine, tertiarybutylarsine (TBA), or any suitable arsenic containing precursor. The arsenic containing precursor may include two or more arsenic containing gases. The arsenic containing precursor may have a flow rate ranging from about 0.1 sccm to about 100 sccm. In some embodiments, a carrier gas, such as nitrogen gas or hydrogen gas, may be flowed with the silicon containing precursor and the arsenic containing precursor. In some embodiments, an etchant may be flowed with the silicon containing precursor and the arsenic containing precursor in order to perform selective etch back to improve selectivity of the Si:As deposition. An example of the etchant is hydrochloric acid.

The amount of excessive point defects in the Si:As layer 204 may be controlled by varying processing conditions, such as partial pressure of the precursors, ratio of the precursors, processing temperature, and/or layer thickness. The amount of excessive point defects in the Si:As layer 204 can control the As atoms diffusion into the third portions 406 of the semiconductor fin 121. During the deposition of the Si:As layer 204, As atoms are diffused into the third portion 406 of the semiconductor fin 121.

At operation 308, the source and drain regions 201 are formed on the Si:As layer 204, as shown in FIG. 4D. The source and drain regions 201 may be a doped semiconductor material, such as phosphorous doped silicon. The source and drain regions 201 may be formed by any suitable method, such as epitaxial deposition process. During the deposition of the source and drain regions 201, As atoms in the Si:As layer 204 continue to diffuse into the third portion 406 of the semiconductor fin 121, and the doped third portions 406 of the semiconductor fin 121 become the source and drain extension regions 202, as shown in FIG. 4D. The source and drain extension regions 202 have a smaller dopant concentration compared to the source and drain regions 201. For example, each source/drain extension region 202 has a dopant concentration of ranging from about 1E17 atoms/cm³ to about 2E20 atoms/cm³. The dopant in the source and drain regions 201 may be the same as or different from the dopant in the source and drain extension regions 202. In one embodiment, the dopant in the source and drain regions 201 is phosphorous and the dopant in the source and drain extension regions 202 is arsenic.

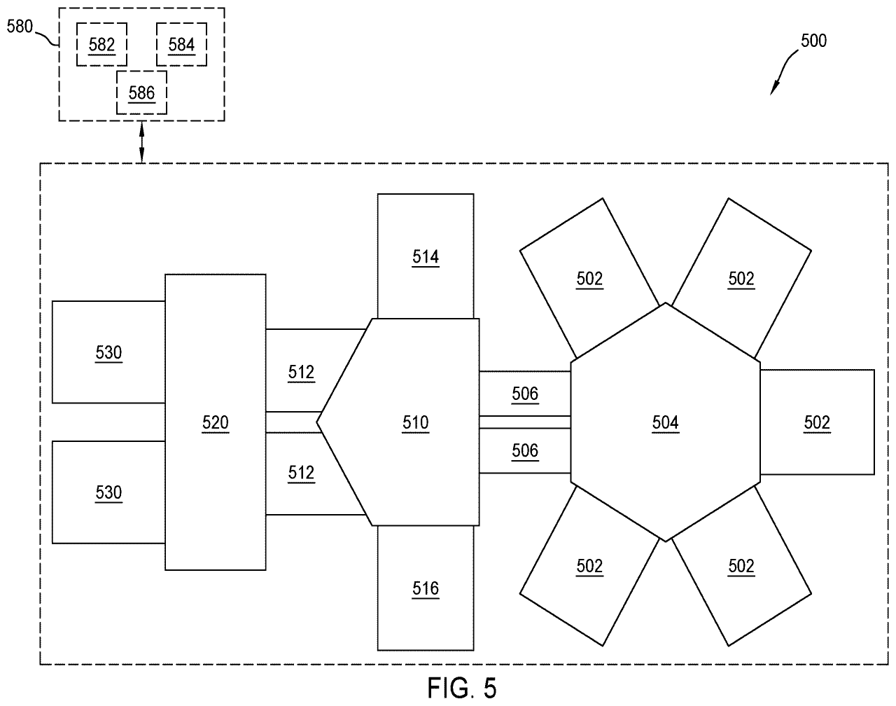

Examples of a processing system that may be suitably modified in accordance with the teachings provided herein include the ENDURA®, PRODUCER® or CENTURA® integrated processing systems or other suitable processing systems commercially available from Applied Materials, Inc., located in Santa Clara, California. It is contemplated that other processing systems (including those from other manufacturers) may be adapted to benefit from aspects described herein. FIG. 5 illustrates a schematic top-view diagram of an example multi-chamber processing system 500 that can be used to complete the method 300 illustrated in FIG. 3, according to embodiments of the present disclosure. As shown in FIG. 5, a plurality of process chambers 502 is coupled to a first transfer chamber 504. The first transfer chamber 504 is also coupled to a first pair of pass-through chambers 506. The first transfer chamber 504 has a centrally disposed transfer robot (not shown) for transferring substrates between the pass-through chambers 506 and the process chambers 502. The pass-through chambers 506 are coupled to a second transfer chamber 510, which is coupled to a process chamber 514 and a process chamber 516. The second transfer chamber 510 has a centrally disposed transfer robot (not shown) for transferring substrates between a set of load lock chamber 512 and the process chamber 514 or the process chamber 516. A factory interface 520 is connected to the second transfer chamber 510 by the load lock chambers 512. The factory interface 520 is coupled to one or more pods 530 on the opposite side of the load lock chambers 512. The pods 530 typically are front opening unified pods (FOUP) that are accessible from a clean room.

During operation, a substrate is first transferred to the process chamber 514, in which operation 302 may be performed. The substrate is then transferred to the process chamber 516, in which operation 304 is performed. Next, the substrate is transferred to the one or more process chambers 502 in which operations 306 and 308 may be performed. Because all of the operations 302, 304, 306, and 308 are performed within the same processing system 500, vacuum is not broken as the substrate is transferred to various chambers, which decreases the chance of contamination and improves the quality of the deposited epitaxial film.

In some embodiments, operation 304 is performed in an etch chamber that is not a part of the processing system 500.

A system controller 580 is coupled to the processing system 500 for controlling the processing system 500 or components thereof. For example, the system controller 580 may control the operations of the processing system 500 using a direct control of the chambers 502, 504, 506, 510, 512, 514, 516 of the processing system 500 or by controlling controllers associated with the chambers 502, 504, 506, 510, 512, 514, 516. In operation, the system controller 580 enables data collection and feedback from the respective chambers to coordinate performance of the processing system 500.

The system controller 580 generally includes a central processing unit (CPU) 582, memory 584, and support circuits 586. The CPU 582 may be one of any form of a general purpose processor that can be used in an industrial setting. The memory 584, non-transitory computer-readable medium, or machine-readable storage device, is accessible by the CPU 582 and may be one or more of memory such as random access memory (RAM), read only memory (ROM), floppy disk, hard disk, or any other form of digital storage, local or remote. The support circuits 586 are coupled to the CPU 582 and may comprise cache, clock circuits, input/output subsystems, power supplies, and the like. The system controller 580 is configured to perform method 300 stored in the memory 584. The various embodiments disclosed in this disclosure may generally be implemented under the control of the CPU 582 by executing computer instruction code stored in the memory 584 (or in memory of a particular process chamber) as, e.g., a computer program product or software routine. That is, the computer program product is tangibly embodied on the memory 584 (or non-transitory computer-readable medium or machine-readable storage device). When the computer instruction code is executed by the CPU 582, the CPU 582 controls the chambers to perform operations in accordance with the various embodiments.

By utilizing Si:As layers between the source and drain regions and source and drain extension regions, doping of the source and drain extension regions is controlled. As a result, the As atoms do not diffuse into the channel region. Furthermore, processes, such as source and drain extension recess and source and drain extension regrowth, are omitted.

While the foregoing is directed to embodiments of the present disclosure, other and further embodiments of the disclosure may be devised without departing from the basic scope thereof, and the scope thereof is determined by the claims that follow.

What is claimed is:

1. A transistor, comprising:
a substrate;
a semiconductor fin disposed over the substrate, the semiconductor fin comprising:
a source region, a drain region, and a channel region disposed between the source region and the drain region; and
a first arsenic-doped silicon layer disposed between the source region and the substrate and between the drain region and the substrate;
a second arsenic-doped silicon layer disposed between the first arsenic-doped silicon layer and the source region and between the first arsenic-doped silicon layer and the drain region; and
a gate electrode structure disposed over the channel region of the semiconductor fin.

2. The transistor of claim 1, wherein the gate electrode structure comprises a gate electrode layer, a gate dielectric layer, and gate spacers.

3. The transistor of claim 2, wherein the gate spacers are disposed over the first arsenic-doped silicon layer.

4. The transistor of claim 1, wherein the source region and the drain region include a dopant other than arsenic.

5. The transistor of claim 1, wherein the source region and the drain region are doped with phosphorous.

6. The transistor of claim 1, wherein the first arsenic-doped silicon layer is disposed between the source region and the channel region and between the drain region and the channel region.

7. The transistor of claim 1, wherein a dopant concentration of the first arsenic-doped silicon layer is at least ten times less than the dopant concentration of each of the source region and the drain region.

8. A method for forming a transistor, comprising:
forming an arsenic-doped silicon layer over a side wall and a bottom of a fin-shaped structure of semiconductor material, wherein
the fin-shaped structure includes a channel region and an outer portion between the channel region and the arsenic-doped silicon layer,
the arsenic-doped silicon layer is formed by a deposition process, and
a gate electrode structure is disposed over the fin-shaped structure; and
forming a source/drain region over the arsenic-doped silicon layer while doping the outer portion of the fin-shaped structure with arsenic.

9. The method of claim 8, wherein a chamber pressure while forming the source/drain region is about 1 Torr to about 600 Torr.

10. The method of claim 8, wherein a temperature while forming the source/drain region is about 500 degrees Celsius to about 700 degrees Celsius.

11. The method of claim 8, further comprising flowing a silicon-containing precursor and an arsenic containing precursor into a process chamber during the deposition process.

12. The method of claim 8, further comprising flowing an etchant into a process chamber during the deposition process to achieve a selective deposition process.

13. The method of claim 8, further comprising doping the outer portion of the fin-shaped structure during the forming of the arsenic-doped silicon layer.

14. The method of claim 8, wherein the outer portion of the fin-shaped structure has a dopant concentration ranging from 1×10¹⁷ atoms/cm³ to 2×10²⁰ atoms/cm³.

15. The method of claim 8, wherein a dopant concentration in the outer portion of the fin-shaped structure is at least ten times less than a dopant concentration in the source/drain region.

16. The method of claim 8, further comprising performing a thermal treatment process on the arsenic-doped silicon layer before forming the source/drain region.

17. The method of claim 16, wherein the thermal treatment process is a spike annealing process.

18. A non-transitory computer readable storage medium having stored thereon a plurality of instructions, the plurality of instructions including instructions to control components of a processing system to perform a process of:
forming an arsenic-doped silicon layer over a side wall and a bottom of a fin-shaped structure of semiconductor material, wherein
the fin-shaped structure includes a channel region and an outer portion between the channel region and the arsenic-doped silicon layer,
the arsenic-doped silicon layer is formed by a deposition process, and
a gate electrode structure is disposed over the fin-shaped structure; and
forming a source/drain region over the arsenic-doped silicon layer while doping the outer portion of the fin-shaped structure with arsenic.

19. The non-transitory computer readable storage medium of claim 18, wherein the plurality of instructions further include instructions to control components of the processing system to maintain a chamber pressure during the deposition process from 1 Torr to 600 Torr.

20. The non-transitory computer readable storage medium of claim 18, wherein the plurality of instructions further include instructions to control components of the processing system to maintain a temperature during the deposition process from 500 degrees Celsius to 700 degrees Celsius.
